(19) United States
(12) Patent Application Publication
(10) Pub. No.: US 2005/0025319 A1
(43) Pub. Date: Feb. 3, 2005

(54) Dodecahedral speaker system

(75) Inventor: Iwao Kawakami, Tokyo (JP)

Correspondence Address: KODA & ANDROLIA, 2029 CENTURY PARK EAST, SUITE 1430, LOS ANGELES, CA, 90067-3024, US

(73) Assignee: Solid Acoustics Co., Ltd.

(21) Appl. No.: 10/902,351

(22) Filed: Jul. 29, 2004

(30) Foreign Application Priority Data
Jul. 31, 2003 (JP) 2003-283916

(51) Int. Cl. H03G 5/00; H04R 1/02

(52) U.S. Cl. 381/103; 381/335

(57) ABSTRACT

A dodecahedral speaker system including a dodecahedral speaker, which is formed with twelve speaker units, and an equalizer circuit, which corrects specified frequency bands of voice signals outputted from the dodecahedral speaker. The equalizer circuit is installed in the pre-stage of the amplifier to which the dodecahedral speaker is connected.

### BACKGROUND OF THE INVENTION

1. Technical Field

The present invention relates to a dodecahedral speaker system that includes a dodecahedral speaker.

2. Description of the Related Art

A conventionally known dodecahedral speaker 3 has, as shown in FIG. 7, twelve (12) speaker units 1, and one speaker unit is embedded in each one of pentagonal outer peripheral faces 2A of a speaker box 2 which of each one of the speaker units and has a substantially dodecahedral shape.

Such a prior art dodecahedral speaker 3 has, however, several problems. Although extremely broad directional characteristics are obtained by means of the twelve speaker units 1 that are uniformly disposed facing outward, the sound pressure shows a drop and variation in a specified frequency band.

In order to solve such a problem, a sound reinforcement device 4 with broad directional characteristics such as the device shown in FIG. 8 has been proposed as shown in, for instance, Japanese Patent Application Laid-Open (Kokai) No. 10-341493. In this sound reinforcement device 4 with broad directional characteristics, the sound pressure characteristics around the entire periphery of the dodecahedral speaker 7 are evened out and smoothed by disposing a corrective filter 8 between the speaker units 6 and the amplifier (not shown in FIG. 8).

However, in this conventional universally known sound reinforcement device 4 that has broad directional characteristics, since a corrective filter 8 is disposed between the speaker units 6 and the amplifier, the voice signal loss and heat generated in the corrective filter 8 are large, and correction of the sound pressure characteristics in the bass region is difficult.

### BRIEF SUMMARY OF THE INVENTION

The present invention is to solve the problems described above.

More specifically, the object of the present invention is to provide a dodecahedral speaker system which makes it possible to realize a reduction in the voice signal loss and generation of heat, and which at the same time makes it possible to even out the sound pressure characteristics in a broad frequency band, and especially to achieve an effective increase in the sound pressure in the bass region of 50 to 500 Hz.

The above object is accomplished by a unique structure of the present invention for a dodecahedral speaker system that includes a dodecahedral speaker which has twelve speaker units, and one of the speaker units is embedded in each of the substantially pentagonal outer peripheral faces of a speaker box that has a substantially dodecahedral shape; and in the present invention, the speaker system further includes an equalizing circuit which corrects a specified frequency band of the a voice signal that is outputted from the dodecahedral speaker, and this equalizing circuit is disposed in the pre-stage of an amplifier to which the dodecahedral speaker is connected.

In the above structure of the present invention, the above-described specified frequency band can be set as the bass region of 50 to 500 Hz; in this frequency region, it is especially desirable to set this region as either 60 to 110 Hz or 200 to 300 Hz.

The above-described specified frequency region can be set as a mid-tone to treble band of either 800 Hz to 1.2 kHz, 1.8 kHz to 2.2 kHz or 12 kHz to 20 kHz.

Furthermore, in the present invention, the speaker system can be designed so that either two, three, four or six of the above-described speaker units are connected in parallel, and the sets of speaker units that are thus connected in parallel are respectively connected in series, so that the above-described twelve speaker units are constructed in a combination of either 6 (six) sets of 2 (two) speaker units per set (2 speaker units×6), four (4) sets of 3 (three) speaker units per set (3 speaker units×4), 3 (three) sets of 4 (4) speaker units per set (4 speaker units×3), or 2 (two) sets of 6 (six) speaker units per set (6 speaker units×2).

Furthermore, the above-described dodecahedral speaker box may be constructed by joining either two, three, four or six sets of speaker box sub-units that have either six, four, three or two faces.

Furthermore, the speaker box can be constructed from a steel or stainless steel plate.

The speaker box can be molded by aluminum die-casting.

In addition, the speaker box can be formed from aluminum, and the inside surfaces and outside surfaces of the speaker box can be subjected to an alumite treatment.

With the structures of the present invention described above, a reduction of voice signal loss and heat generation are realized, and at the same time, the sound pressure characteristics are evened out in a broad frequency band; in particular, the sound pressure in the bass region of 50 to 500 Hz is effectively increased.

In short, the object of evening out the sound pressure characteristics in a broad frequency band is realized while reducing voice signal loss and heat generation.

### BRIEF DESCRIPTION OF THE SEVERAL VIEWS OF THE DRAWINGS

FIG. 1 is a schematic structural diagram of a dodecahedral speaker system according to one embodiment of the present invention;

FIG. 2 is a schematic front view of the dodecahedral speaker of FIG. 1;

FIG. 3 is a circuit diagram of the equalizer circuit used in the system of FIG. 1;

FIG. 4A is a graph showing the sound pressure characteristics prior to correction by the equalizer circuit shown of FIG. 1, and FIG. 4B is a graph showing the sound pressure characteristics after correction by the equalizer circuit shown of FIG. 1, wherein the sound pressure plotted on the vertical axis and the frequency plotted on the horizontal axis;

FIG. 5A through 5C are schematic diagrams of the dodecahedral speaker system according to other embodiments of the present invention;

FIG. 6((A) through (C)) show the steps of forming the speaker box used in the system of FIG. 1;

FIG. 7 is a schematic front view of a conventional dodecahedral speaker; and

FIG. 8 is a schematic structural diagram of a conventional sound reinforcement device with broad directional characteristics.

### DETAILED DESCRIPTION OF THE INVENTION

Embodiments of the present invention will be described below with reference to the accompanying drawings.

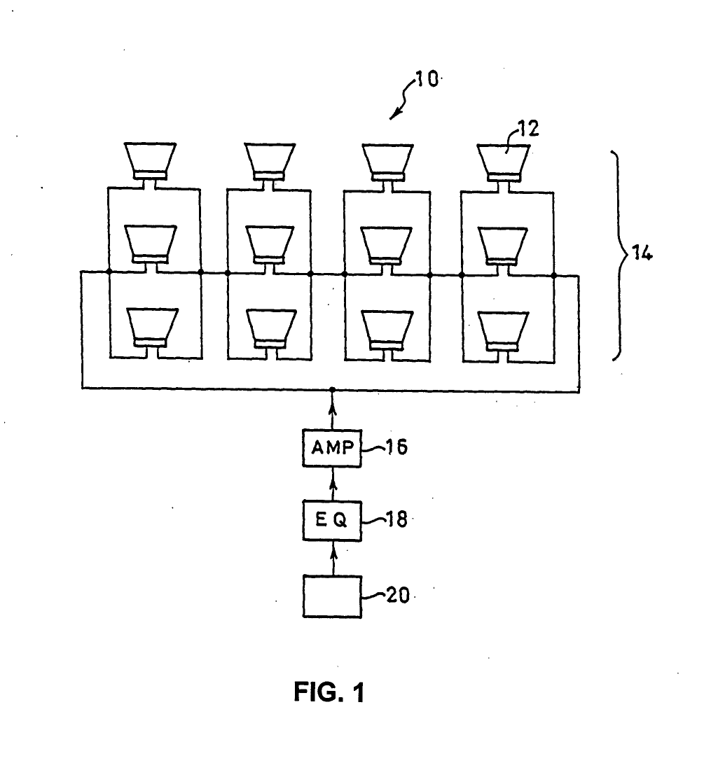

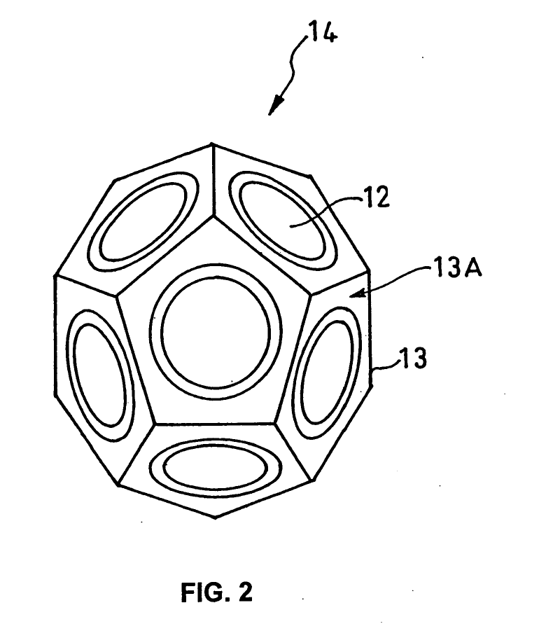

As shown in FIGS. 1 and 2, the dodecahedral speaker system 10 of one embodiment of the present invention includes a dodecahedral speaker 14 comprised of twelve speaker units 12, an amplifier 16 which is connected to this dodecahedral speaker 14, an equalizer circuit 18 which is disposed in the pre-stage of this amplifier 16, and a playback device 20.

In terms of the structure of the speaker itself, the dodecahedral speaker 14 is similar to the conventional dodecahedral speaker 3 shown in FIG. 7; and this speaker 14 has twelve (12) speaker units 12, with one speaker unit 12 being embedded in each of the pentagonal outer peripheral faces 13A of a speaker box 13 that has the shape of a regular dodecahedron. The speaker box 13 of a substantially dodecahedron shape is molded by aluminum die-casting (as will be described below). In the shown embodiment, the speaker units 12 are non-directional full-range speakers. The respective speaker units 12 are arranged so that three (3) speaker units are connected in parallel, and these three sets consisting of speaker units connected in parallel are connected in series; thus, the dodecahedral speaker 14 is constructed from a combination of four sets of three speaker units (three (3) speaker units×4) each.

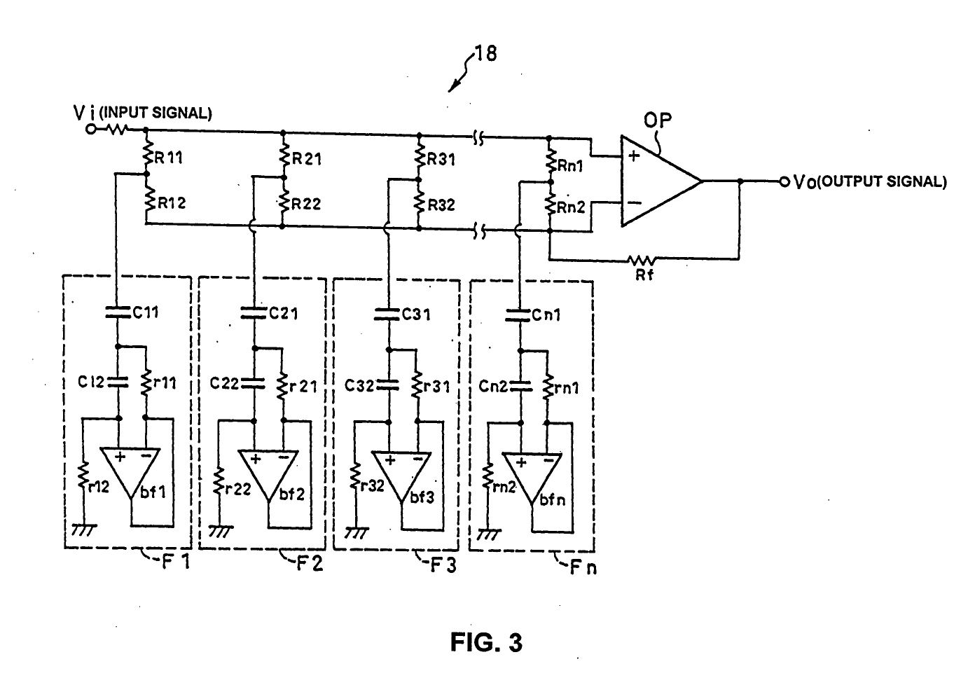

The equalizer circuit 18 is installed as seen from FIG. 1 in the pre-stage of (or before in terms of signal flow) the amplifier 16 (so as to be between the amplifier 16 and a playback device 20); and it is, as shown by the circuit diagram of FIG. 3, constructed from an operational amplifier OP in which an input signal Vi is inputted into a non-inverted input terminal, and a feedback resistor Rf is connected between an inverted input terminal and an output terminal that outputs an output signal Vo, and a plurality of semiconductor inductors F1 through Fn that are connected between the two input terminals of this operational amplifier OP via resistors R11 and R12 through Rn1 and Rn2. These semiconductor inductors F1 through Fn comprise capacitors C12 through Cn2 which are connected in series with capacitors C11 through Cn1, resistors r12 through rn2 which are connected in series with these capacitors at one ends and whose other ends are grounded, and buffer amplifiers bf1 through bfn which limit the current that flows to the resistors r12 through m2 from between the capacitors C12 through Cn2 and resistors r11 through m1. These semiconductor inductors F1 through Fn are installed only for specified frequency bands for which correction of the sound pressure is performed, and the resistance values and capacitance values of the respective semiconductor inductors F1 through Fn are set in accordance with specified frequencies.

As seen from the above, the equalizer circuit 18 is constructed so that the amount of sound pressure boost and amount of sound pressure cutting can be adjusted by adjusting the resistance values of the sets of resistors R11, R12 through Rn1, Rn2 installed for each of the respective semiconductor inductors F1 through Fn.

Next, the operation of the dodecahedral speaker system 10 will be described.

A voice signal (prior to being amplified) that is outputted from a playback device 20 such as a CD player, etc. is inputted into the equalizer circuit 18, and correction of a specified frequency band of this voice signal is performed on the basis of an amount of boost and amount of cutting that have been adjusted beforehand.

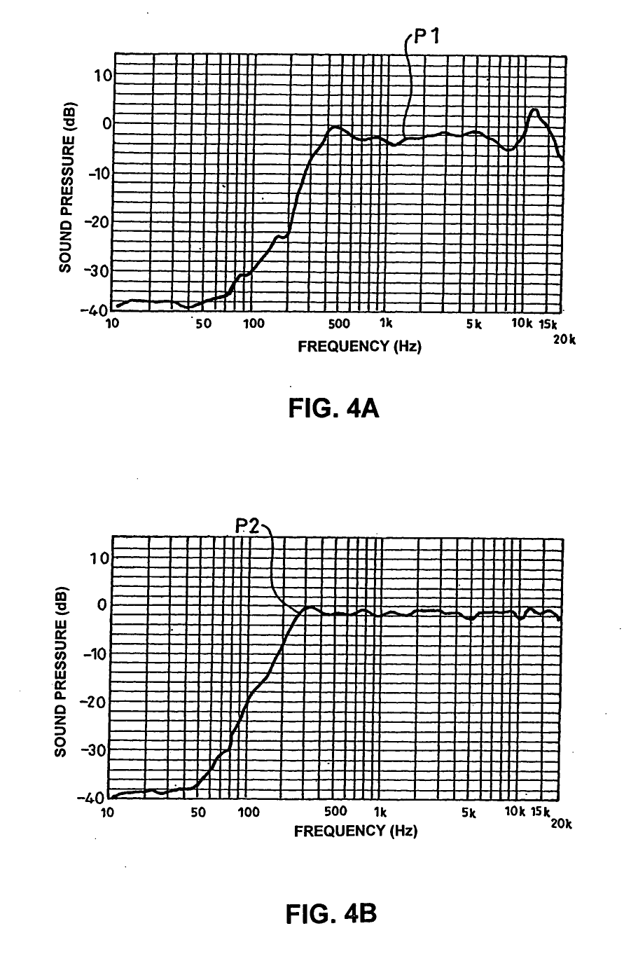

For example, a case will be considered in which the dodecahedral speaker 14 prior to correction has sound pressure characteristics P1 such as those shown in FIG. 4 (A).

In this case, the sound pressure is low in the bass region of 50 to 500 Hz and in the frequency band around 8 kHz, and the sound pressure is high in the treble region of 10 to 15 kHz. Accordingly, in order to even out the sound pressure characteristics, it is desirable to correct the sound pressure in these three frequency bands. Therefore, if semiconductor inductors F1 through F3 corresponding to these three frequency bands are installed in the equalizer circuit 18, and the resistance values of the resistors R11, R12, R21, R22, R31 and R32 are adjusted so that the bass region of 50 to 500 Hz and the frequency band around 8 kHz are boosted by a specified amount, and so that the treble region of 10 to 15 kHz is cut by a specified amount, then sound pressure characteristics P2 that are evened out as shown in FIG. 4B can be obtained.

Furthermore, the voice signal that is corrected by the equalizer circuit 18 is amplified by the amplifier 16 and is then outputted from the respective speaker units 12 of the dodecahedral speaker 14.

In the present invention, the equalizer circuit 18 that corrects specified frequency bands of the voice signal that is outputted from the dodecahedral speaker 14 is provided, and this equalizer circuit 18 is installed in the pre-stage of (or before) the amplifier 16 to which the dodecahedral speaker 14 is connected. Accordingly, the sound pressure characteristics are evened out in a broad frequency band. In particular, the sound pressure in the bass region of 50 to 500 Hz effectively increases. Furthermore, since a voice signal with a small pre-amplification level is inputted into the equalizer circuit 18, the voice signal loss and generation of heat are reduced. Moreover, especially if the bass region of either 60 to 110 Hz or 200 to 300 Hz and the mid-tone to treble region of any of the bands of 800 kHz to 1.2 kHz, 1.8 to 2.2 kHz an 12 to 20 kHz (among the frequency bands of the voice signal) are corrected by the equalizer circuit 18, the effect in evening out the sound pressure characteristics greatly increases.

Furthermore, three speaker units 12 are connected in parallel, these sets comprising the speaker units 12 that are connected in parallel are respectively connected in series, and the dodecahedral speaker 14 is constructed from a combination of four sets of three speaker units each; accordingly, the impedance in the respective speaker units 12 is uniform, and variation in the amount of vibration of the speaker units 12 is eliminated. In cases where one of the twelve speaker units 12 malfunctions, the other eleven speaker units 12 can output the voice signal without being affected by this malfunction.

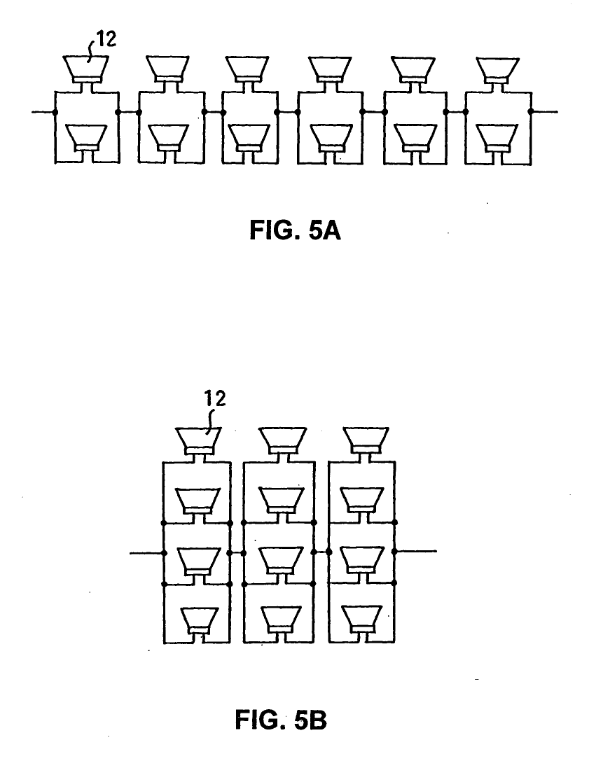

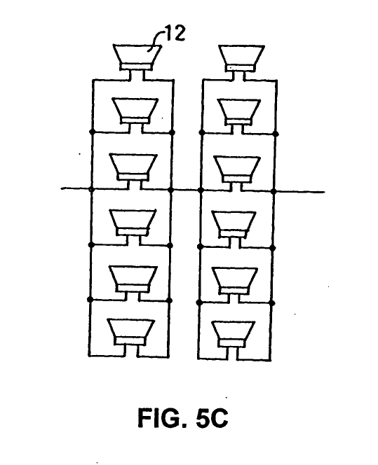

In the above-described embodiment, the dodecahedral speaker 14 is constructed from four sets of three speaker units 12 each. However, the present invention is not limited to this structure. For example, as shown in FIGS. 5A through 5C, either two, four or six speaker units 12 can be connected in parallel, and these sets consisting of (two, four or six) speaker units connected in parallel can be respectively connected in series, so that the twelve speaker units are constructed in a combination of six sets of two speaker units each, three sets of four speaker units each or two sets of six speaker units each.

Next, a method for forming the above-described speaker box 13 will be described.

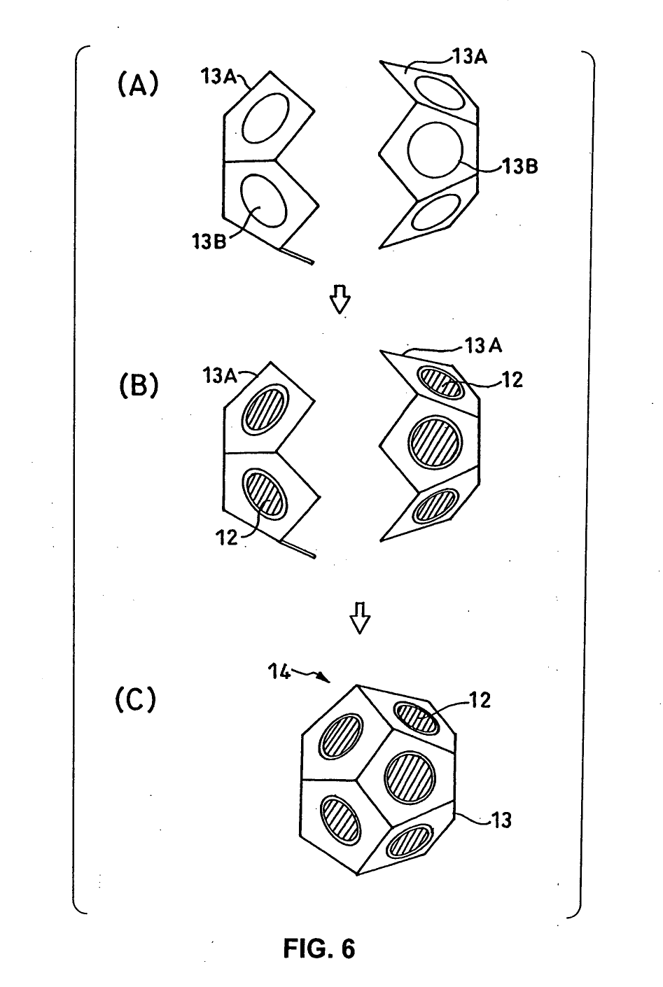

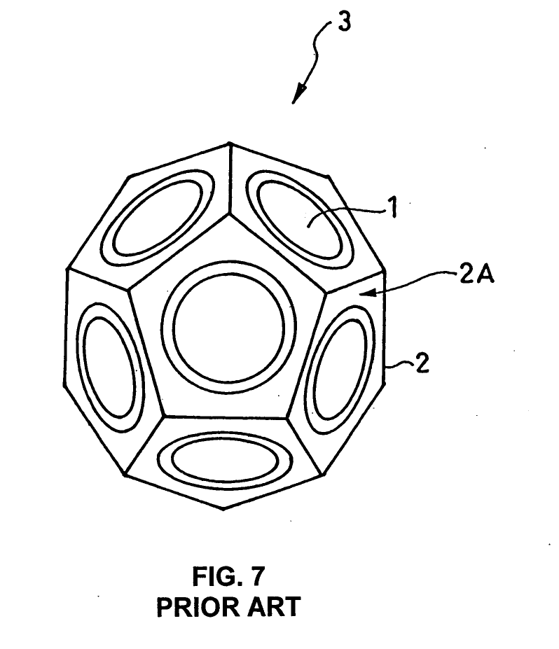

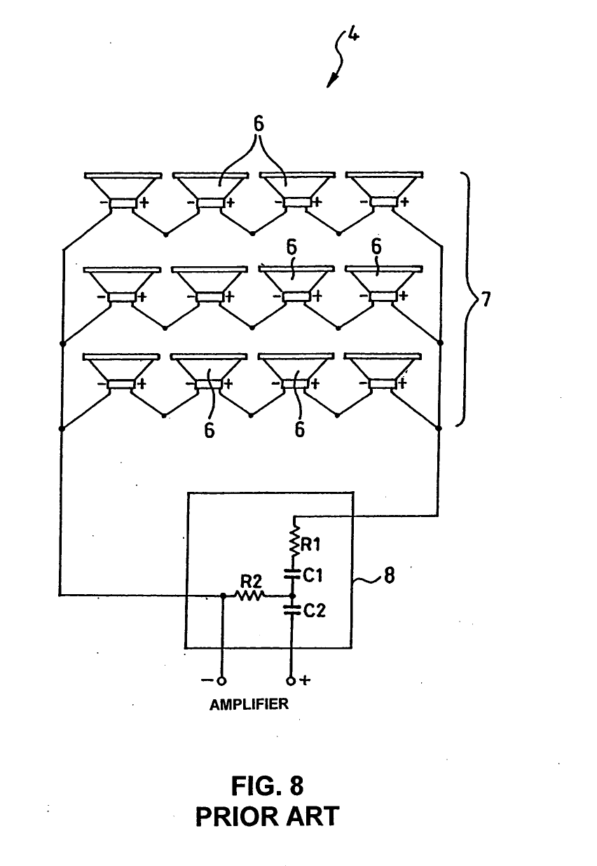

As shown in (A) in FIG. 6, two speaker box sub-units 13A are molded into an integral body by aluminum die casting. Each of these speaker box sub-units 13A is formed in the shape of a half section that has six faces, and a speaker hole 13B that is used to install a speaker unit 12 is formed in each regular pentagonal face.

Next, after an alumite treatment is performed on the inside surface and outside surface of each of the speaker box sub-units 13A, speaker units 12 are respectively embedded in the speaker holes 13B (see (B) of FIG. 6). Here, the term “alumite treatment” refers to a treatment in which a coating film is formed by oxidizing the surface of aluminum metal. As a result of such an alumite treatment being performed, the heat dissipation characteristics of the speaker box 13 are enhanced, and corrosion and oxidation, etc. of the inside and outside surfaces of the speaker box 13 are prevented, so that the durability improves.

Finally, the two speaker box sub-units 13A are joined by welding, thus forming the dodecahedral speaker 14 as shown in (C) of FIG. 6.

In the speaker box 13 thus formed by aluminum die-casting, it is possible for a speaker box 13 to have a complex shape, and it can easily be worked with a small thickness. Accordingly, the speaker box 13 has improved heat dissipation characteristics, and the weight of the speaker box can be reduced.

Furthermore, the speaker box 13 can be formed with a steel plate or a stainless steel plate. In this structure, the speaker box 13 can be worked with a small thickness, corrosion and oxidation, etc. can be prevented, and the rigidity increases.

In the above description, the speaker box 13 is constructed by joining two speaker box sub-units 13A each having six faces. However, the present invention is not limited to such a construction. For example, it is also be possible to construct the speaker box by joining three, four or six speaker box sub-units each having four, three or two faces.

The “equalizer circuit” in the present invention is not limited to the circuit construction shown in the above-described embodiment; and any circuit construction that is capable of correcting specified frequency bands of the voice signal can be used.

The speaker system of the present invention can be used in hi-fi audio and acoustic measurements, etc. and is especially ideal for use in English hearing tests, etc. in which broad directional characteristics are required.

1. A dodecahedral speaker system equipped with a dodecahedral speaker which has twelve speaker units, wherein one of said speaker units is embedded in each of pentagonal outer peripheral faces of a speaker box that has a substantially dodecahedral shape, and wherein said speaker system is further comprised of an equalizing circuit which corrects a specified frequency band of a voice signal that is outputted from said dodecahedral speaker, and said equalizing circuit is disposed in pre-stage of an amplifier to which said dodecahedral speaker is connected.

2. The dodecahedral speaker system according to claim 1, wherein said specified frequency band is a bass band of 50 to 500 Hz.

3. The dodecahedral speaker system according to claim 2, wherein said specified frequency band is a bass band of one selected from the group consisting of 60 to 100 Hz and 200 to 300 Hz.

4. The dodecahedral speaker system according to claim 1, wherein said specified frequency band is a mid-tone to treble band of one selected from the group consisting of 800 Hz to 1.2 kHz, 1.8 kHz to 2.2 kHz and 12 kHz to 20 kHz.

5. The dodecahedral speaker system according to claim 1, wherein
said speaker units are connected in parallel by the number of one selected from two, three, four and six;
sets of speaker units that are thus connected in parallel are respectively connected in series; and
said twelve speaker units are put in one combination selected from the group of six sets of two speaker units, four sets of three speaker units, three sets of four speaker units and two sets of six speaker units.

6. The dodecahedral speaker system according to claim 1, wherein said dodecahedral speaker box is constructed by one combination selected from the group of two sets of speaker box sub-units each having six faces, three sets of speaker box sub-units each having four faces, four sets of speaker box sub-units each having three faces, six sets of speaker box sub-units each having two faces.

7. The dodecahedral speaker system according to claim 1, wherein said speaker box is molded by aluminum die-casting.

8. The dodecahedral speaker system according to claim 1, wherein said speaker box is constructed from one selected from the group consisting of a steel plate and a stainless steel plate.

9. The dodecahedral speaker system according to claim 1, wherein said speaker box is formed from aluminum, and inside surfaces and outside surfaces of said speaker box are subjected to an alumite treatment.
